(19) United States
(12) Patent Application Publication
(10) Pub. No.: US 2025/0052608 A1
(43) Pub. Date: Feb. 13, 2025

(54) INSPECTING TOOL FOR INSPECTING MICRO LED ARRAY PANEL

(71) Applicant: JADE BIRD DISPLAY (SHANGHAI) LIMITED, SHANGHAI (CN)

(72) Inventors: Chenchao XU, Shanghai (CN); Yang YUE, Shanghai (CN); Qiming LI, Shanghai (CN)

(21) Appl. No.: 18/719,847

(22) PCT Filed: Dec. 16, 2021
(86) PCT No.: PCT/CN2021/138838

§ 371 Date: Jun. 14, 2024

(51) Int. Cl. G01J 1/42

(52) U.S. Cl. CPC G01J 1/42; G01J 2001/4252

(57) ABSTRACT

An inspecting tool for inspecting a micro LED array panel (00) includes: an optical collector group (01) configured to collect light emitted from a micro LED array included in the micro LED array panel (00); an image detector (02) connected with the optical collector group (01) to receive the light collected by the optical collector group (01), and configured to capture an image of the micro LED array; and a light measuring device (03) electrically connected with the optical collector group (01) receive the light collected by the optical collector group (01), and configured to measure the light emitted from one or more portions of the micro LED array. The optical collector group (01) is configured to receive the light emitted from any position of the micro LED array.

### FIELD OF THE DISCLOSURE

The present disclosure generally relates to a light emitting diode technology field and, more particularly, to an inspecting tool for inspecting a micro light emitting diode (LED) array panel.

### BACKGROUND OF THE DISCLOSURE

Micro LED with extra small area and high resolution is increasingly popular in the world. A micro LED array panel can be used to form various kinds of devices, such as camera module, projection modules, display modules, VR/AR optical modules and so on.

However, because a light emitting area and an image displayed by the micro LED array panel are much smaller than before, pixel defects of the micro LED array panel are not easy to be detected and identified by conventional methods. Thus, operators need to review a wafer, a chip, and a mask through a graphical user interface displaying various pattern images of the micro LED panel, so as to identify pattern defects.

Additionally, the light emitting area of the micro LED array panel is very small, such as 3 mm*5 mm. But a collecting area of an optical collector for collecting the light emitted by a micro LED array on the micro LED array panel cannot be as small as a light emitting area of the micro LED array panel due to the various optical components in the optical collector. Thus, an image collecting process and a light collecting process cannot be performed at the same time. Furthermore, if the image collecting process and the light collecting process are performed at the same time, the light entered into the optical collector will be weakened, thereby decreasing the image accuracy and the measuring accuracy.

The above content is only used to assist in understanding the technical solutions of the present application and does not constitute an admission that the above is prior art.

### BRIEF SUMMARY OF THE DISCLOSURE

In order to overcome the drawback mentioned above, the present disclosure provides an inspecting tool for inspecting a micro LED array panel, to improve the detection efficiency and the detection accuracy.

To achieve the above objective, the present disclosure provides an inspecting tool for detecting the micro LED array panel, to increase the light amount entering into the optical collector.

An inspecting tool for inspecting a micro light emitting diode (LED) array panel according to the present disclosure, comprising:
an optical collector group configured to collect light emitted from a micro LED array included in the micro LED array panel;
an image detector connected with the optical collector group to receive the light collected by the optical collector group, and configured to capture an image of the micro LED array; and
a light measuring device electrically connected with the optical collector group to receive the light collected by the optical collector group, and configured to measure the light emitted from one or more portions of the micro LED array,
wherein the optical collector group is configured to receive the light emitted from any position of the micro LED array.

In some embodiments, the optical collector group comprises a first optical collector and a second optical collector; wherein, the first optical collector is connected with the image detector; the second optical collector is electrically connected with the light measuring device; the first optical collector is disposed above and vertically aligned with the micro LED array; and the first optical collector is configured to direct the light emitted from the micro LED array to the image detector.

In some embodiments, one or more portions of the second optical collector has a concave curved surface facing the micro LED array panel.

In some embodiments, the second optical collector is configured to at least comprise the concave curved surface at one or more sides of the first optical collector or around the first optical collector and above the micro LED array panel, and the micro LED array panel is arranged at a center of the concave curved surface, the concave curved surface being used for collecting the light emitted from one or more portions of the micro LED array.

In some embodiments, the second optical collector is not connected with the first optical collector and does not contact a sidewall of the first optical collector.

In some embodiments, an optical transmitting channel is configured between the first optical collector and the image detector; wherein, the second optical collector is configured at least comprising the concave curved surface at one or more sides of the optical transmitting channel or around the optical transmitting channel, and above the micro LED array panel, and the micro LED array panel is arranged at a center of the concave curved surface, the concave curved surface being used for collecting the light emitted from one or more portions of the micro LED array.

In some embodiments, the second optical collector is not connected with the optical transmitting channel and does not contact the sidewall of the optical transmitting channel.

In some embodiments, a filter is arranged between the first optical collector and the image detector.

In some embodiments, the second optical collector is configured at least comprising the concave curved surface at one or more sides of the micro LED array panel or around the micro LED array panel, and the micro LED array panel is arranged at a center of the concave curved surface, the concave curved surface being used for collecting the light emitted from one or more portions of the micro LED array.

In some embodiments, the second optical collector is an integrating semi-sphere with the micro LED array panel disposed in the center of the semi-sphere; wherein, an opening is formed at atop of the semi-sphere for inserting the first optical collector.

In some embodiments, the whole surface of the second optical collector is curved.

In some embodiments, a detecting area of the first optical collector is not less than a light emitting area of the micro LED array.

In some embodiments, a detecting area of the second optical collector is larger than the light emitting area of the micro LED array.

In some embodiments, a detecting area of the second optical collector is less than or equal to the light emitting area of the micro LED array.

To achieve the above objective, an inspecting system for inspecting the micro LED array panel at least comprises an aforementioned inspecting tool.

In some embodiments, the optical collector group comprises a first optical collector and a second optical collector; wherein, the first optical collector is connected with the image detector; and, the second optical collector is connected with the light measuring device; the first optical collector is disposed above and vertically aligned with the micro LED array; and the first optical collector is configured to direct the light emitted from the micro LED array to the image detector.

In some embodiments, the inspecting system further comprises a sample stage, for supporting the micro LED array panel.

In some embodiments, the second optical collector is installed on the sample stage.

Many other advantages and features of the present disclosure will be further understood by the following detailed descriptions and the appended drawings.

### BRIEF DESCRIPTION OF THE DRAWINGS

FIG. 1 is a block diagram illustrating an inspecting tool for inspecting a micro LED array panel according to an embodiment of the present disclosure.

FIGS. 2-25 are schematic diagrams illustrating configurations of the inspecting tool according to various embodiments of the present disclosure.

### DETAILED DESCRIPTION OF THE EMBODIMENTS

Reference will now be made in detail to the present preferred embodiments to provide a further understanding of the disclosure. The specific embodiments and the accompanying drawings discussed are merely illustrative of specific ways to make and use the disclosure, and do not limit the scope of the disclosure or the appended claims.

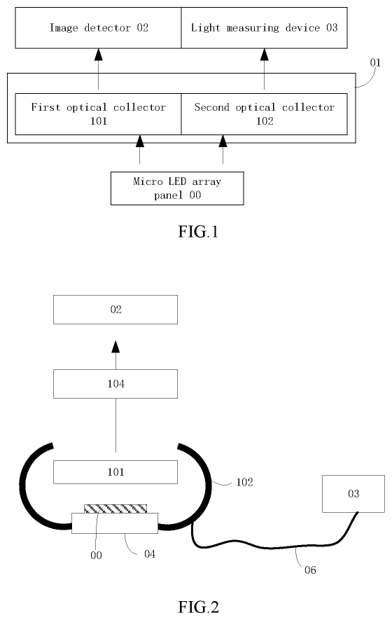

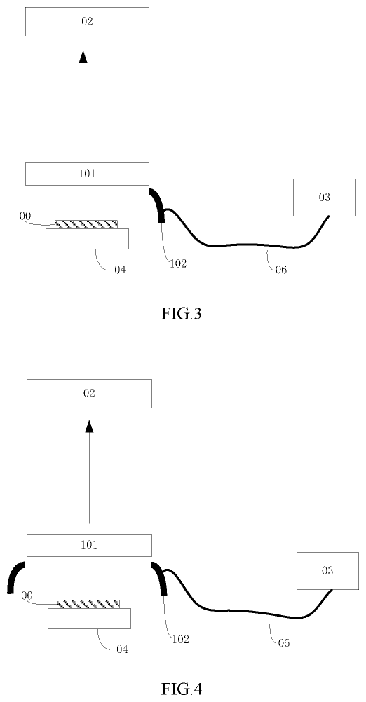

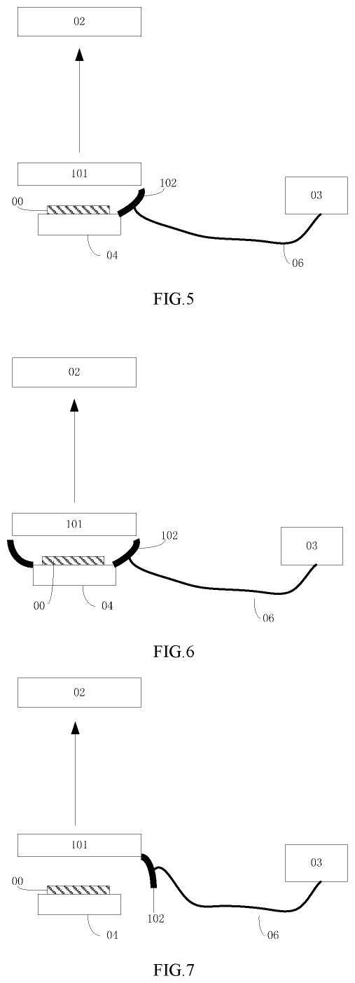

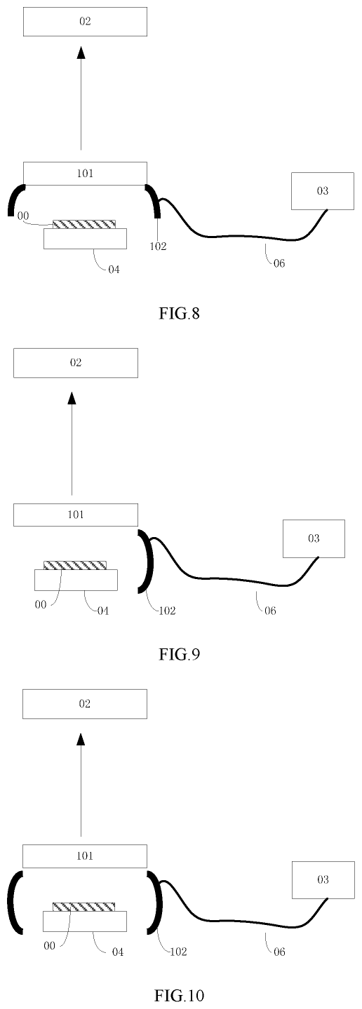

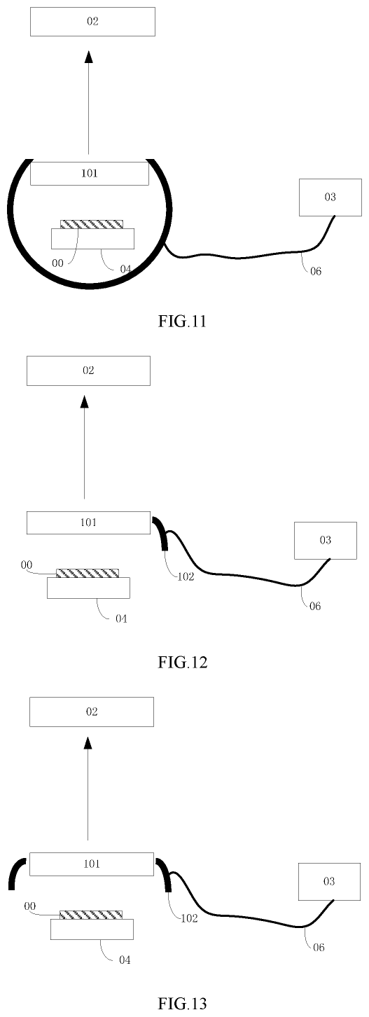

Referring to FIGS. 1 and 2, an inspecting tool for inspecting a micro LED array panel of an embodiment of the present disclosure comprises:
an optical collector group 01 configured to collect light emitted from a micro LED array included in the micro LED array panel 00;
an image detector 02 connected with the optical collector group 01 to receive the light collected by the optical collector group 01, and configured to capture an image of the micro LED array; and
a light measuring device 03 electrically connected with the optical collector group 01 to receive the light collected by the optical collector group, for detecting light emitted from one or more portions of the micro LED array;
wherein, the optical collector group 01 is configured to receive the light emitted from any position of the micro LED array.

Additionally, the image detector 02 may include, but not limited to, a charge coupled device detector, a photo multiplier tube detector, or the like. The light measuring device 03 may include, but not limited to, a spectrometer. The light measuring device 03 can measure any optical parameters of the emitting light such as half-peak breadth, the peak breadth and so on.

The optical collector group 01 comprises a first optical collector 101 and a second optical collector 102; wherein, the first optical collector 101 is connected with the image detector 02; and, the second optical collector 102 is electrically connected with the light measuring device 03; the first optical collector 101 is disposed above and vertically aligned with the micro LED array panel 00; the first optical collector 101 directs the light emitted from the micro LED array panel 00 to the image detector 02.

Furthermore, one or more portions of the second optical collector 102 comprise a concave curved surface facing the micro LED array panel 00. The concave curved surface may have an inwardly concave shape, which is similar to a piece of an edge of a dish or a bowl. Preferably, the whole surface of the second optical collector 102 may be curved. Herein, the first optical collector 101 comprises various optical components to collect and direct the light emitted from the micro LED array. The optical components may comprise lenses, mirrors, filters, beam splitters, and the like. Referring to FIG. 2, for example, a filter 104 may be arranged in the light path between the first optical collector 101 and the image detector 02, for filtering the unexpected lights or weakening the light strength. It is noted that, the second optical collector 102 may be electrically connected with the light measuring device 03 via a conductive line 06. The conductive line 06 may comprise an optical fiber. In some embodiments, the second optical collector may include a light converging device converging the light collected by the concave curved surface to an end of the conductive line 06.

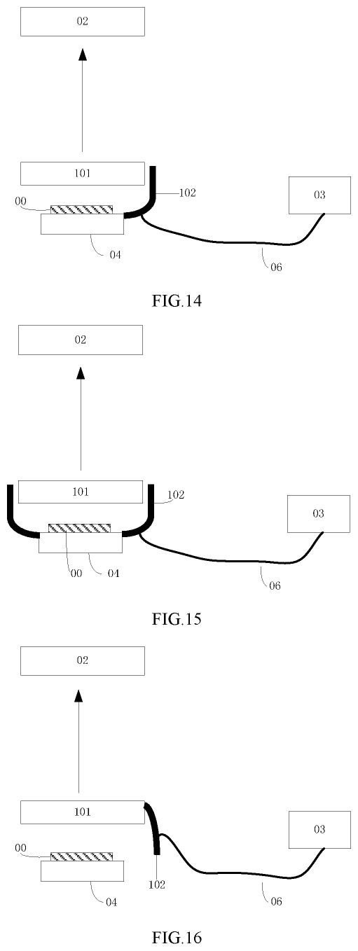

Referring to FIGS. 3 and 4, the second optical collector 102 is configured to at least comprise the concave curved surface below one or more sides of the first optical collector 101 or around the bottom of the first optical collector 101, and above the micro LED array panel 00; and, the concave curved surface is used for collecting the light emitted from one or more portions of the micro LED array. For example, as shown in FIG. 3, which is a sectional view of the inspection tool according to one embodiment, the second optical collector 102 comprises one portion of the concave curved surface below one side of the first optical collector 101. As another example, as shown in FIG. 4, which is a sectional view of the inspection tool according to another embodiment, the second optical collector 102 comprises the entire concave curved surface that surrounds the bottom of the first optical collector 101. Additionally, the second optical collector 102 is not connected with the first optical collector 101 and does not contact the sidewall of the first optical collector 101. Referring to FIGS. 5 and 6, the second optical collector 102 can be installed on a sample stage 04 for supporting the micro LED array panel 00. Referring to FIGS. 7 and 8, the second optical collector 102 can be installed on the first optical collector 101 for supporting the micro LED array panel 00. Preferably, at least one point or the center of the micro LED array panel 00 is arranged at the center of the concave curved surface.

Furthermore, referring to FIGS. 9 and 10, the second optical collector 102 is configured to comprise the concave curved surface at one or more sides of the micro LED array panel 00 or around the micro LED array panel 00; preferably, the micro LED array panel 00 is arranged at the center of the concave curved surface, for collecting the light emitted from one or more portions of the micro LED array. Preferably, the concave curved surface is a semi-sphere. It is noted that, the bottom of the second optical collector 102 can be below the bottom of the micro LED array panel 00.

Furthermore, referring to FIG. 11, the second optical collector 102 is a sphere. For example, the second optical collector 102 may be an integrating semi-sphere; preferably, the micro LED array panel 00 is disposed at the center of the semi-sphere. Herein, an opening is formed in the top of the sphere for inserting the first optical collector 101.

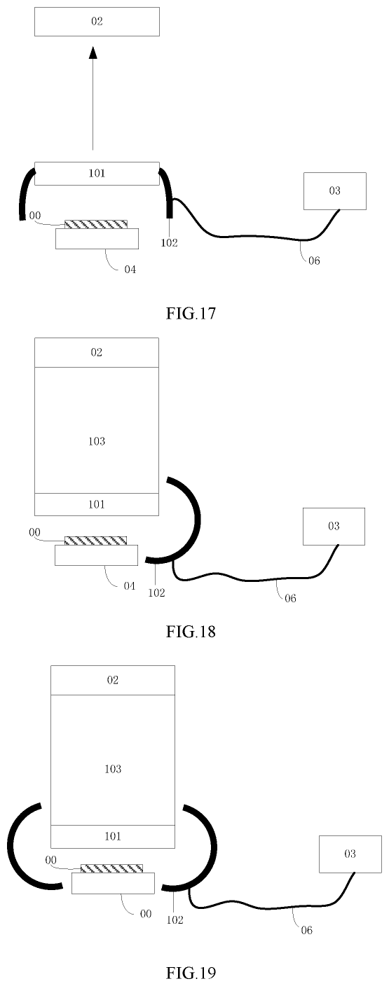

Referring to FIGS. 12 and 13, the second optical collector 102 is configured to comprise the concave curved surface at one or more sides of the first optical collector 101, or around the first optical collector 101 and above the micro LED array panel 00; and, the concave curved surface is used for collecting the light emitted from one or more portions of the micro LED array. Additionally, the second optical collector 102 is not connected with the first optical collector 101 and does not contact the sidewall of the first optical collector 101. Preferably, the micro LED array panel 00 is arranged at the center of the concave curved surface. Referring to FIGS. 14-17, the second optical collector 102 can be installed on the first optical collector 101 or on a sample stage 04 for supporting the micro LED array panel 00. Preferably, at least one point or the center of the micro LED array panel 00 is arranged at the center of the concave curved surface.

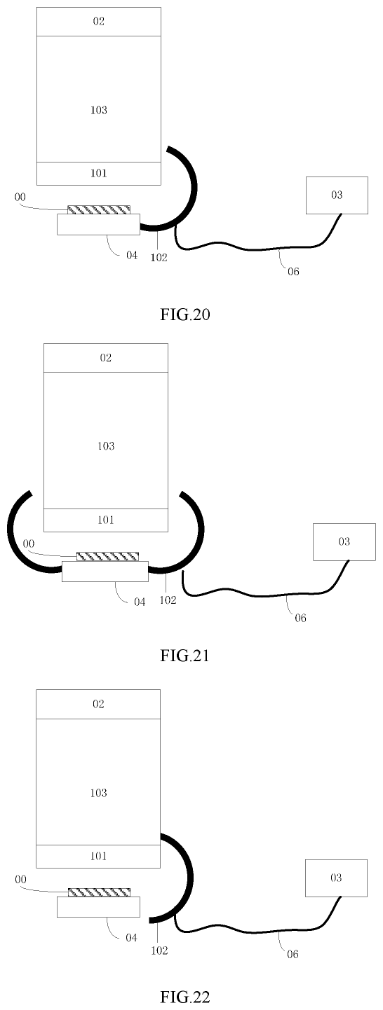

Furthermore, referring to FIGS. 18 and 19, an optical transmitting channel 103 is configured between the first optical collector 101 and the image detector 02. As shown in FIGS. 18 and 19, the second optical collector 102 is configured to comprise the concave curved surface at one or more sides of the optical transmitting channel 103 or around the optical transmitting channel 103, and above the micro LED array panel 00; preferably, the micro LED array panel 00 is arranged at the center of the concave curved surface, the second optical collector 102 is used for collecting the light emitted from one or more portions of the micro LED array. Furthermore, the second optical collector 102 is not connected with the optical transmitting channel 103 and does not contact the sidewall of the optical transmitting channel 103. Referring to FIGS. 20-23, the second optical collector 102 can be installed on the optical transmitting channel 103 or on a sample stage 04 for supporting the micro LED array panel 00. Additionally, the second optical collector 102 may be configured to comprise the concave curved surface around the optical transmitting channel 103 and above the micro LED array panel 00, and the micro LED array panel 00 is arranged at the center of the concave curved surface, for collecting the light emitted from one or more portions of the micro LED array.

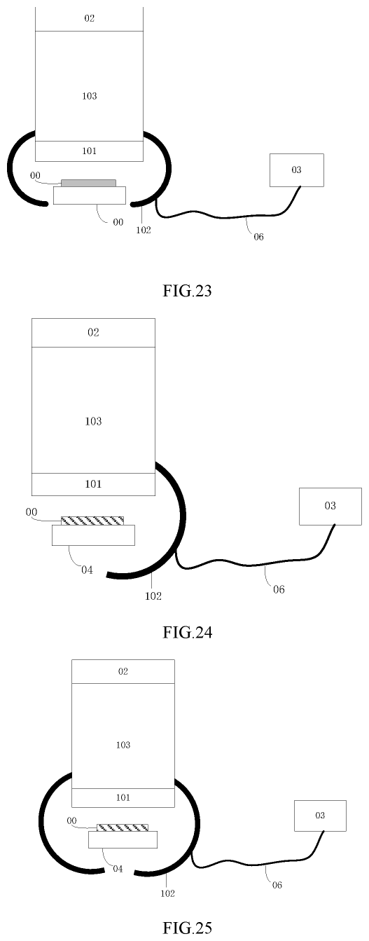

Referring to FIGS. 24 and 25, the bottom of the second optical collector 102 can be below the micro LED array panel 00.

The aforementioned inspecting tool may be used for any system for detecting the micro LED array panel; such as a pixel defect inspecting system, an optical inspecting system, and so on. Additionally, the micro LED array panel 00 may be one piece of panel; or, the micro LED array panel can be replaced by more pieces of panels disposed in one wafer. The micro LED array panel 00 is supported on the sample stage 04. The sample stage 04 may move at any direction and/or rotating at any angle, to align the micro LED array panel 00 with the first optical collector 101.

It is noted that, the second optical collector 102 may be installed on the sample stage 04 or on any other positions of the inspecting system, such as a fixture for installing imaging collector 02 or the first optical collector 101 and so on. During operation, the first optical collector 101 may be adjusted to an optimized position for acquiring one or more parts of a clear image of the micro LED array. When the micro LED array panel 00 is aligned with the first optical collector 101, the inspecting process can be started without adjusting the position of the second optical collector 102. That is to say, the aforementioned position of the second optical collector 102 is optimized position for collecting the light emitted from one or more ports of the micro LED array.

The micro LED array panel 00 is a micro self-emitting panel. The LED in the panel may be an organic LED or an inorganic LED. The light emitting area of the micro LED array panel 00 is very small, such as 3 mm*5 mm. It is noted that, the light emitting area is the area of the micro LED array. The micro LED array panel comprises a micro LED array that forms a pixel array, such as 1600×1200, 680×480, 1920×1080. The diameter of the micro LED is in the range of 200 nm˜2 μm. But the collecting area of the first optical collector 101 cannot be as small as the light emitting area of the micro LED array panel 00 due to the various optical components in the first optical collector 101, which prevents the light directly arriving at the second optical collector 102 if the first optical collector 101 is arranged in the vertical direction. Thus, the configuration of the first optical collector 101 and the second optical collector 102 in the embodiments of the present disclosure can solve this problem. An IC back plane is formed at the back surface of the micro LED array and electrically connected with the micro LED array. The IC back plane acquires signals such as image data from outside via signal lines to control a corresponding micro LED to emit light. The IC back plane generally employs an 8-bit Digital to analog converter (DAC). The 8-bit DAC has 256 levels of manifestations, and each level corresponds to one gray level, that is, the 8-bit DAC may provide 256 different gray levels. Since any one of the 256 gray levels may be applied on the micro LED, a gray level ranging from 0 to 255 may be displayed by one pixel. Optionally, a brightness value of the micro LED can be controlled by voltage amplitudes or current amplitudes of the signals acquired by the IC back plane, while the gray levels can be shown by time intervals, e.g., pulse widths, of the signals.

In the embodiment, a detecting area of the first optical collector 101 is larger than a light emitting area of the micro LED array. In another embodiment, the detecting area of the first optical collector 101 may be equal to the light emitting area of the micro LED array.

Additionally, the detecting area of the second optical collector 102 is larger than the light emitting area of the micro LED array according to the embodiment. In another embodiment, the detecting area of the second optical collector 102 may be less than or equal to the light emitting area of the micro LED array.

It is noted that, the first optical collector 101 and the second optical collector 102 are separately arranged in the embodiments. But in another embodiments, the first optical collector 101 and the second optical collector 102 can be configured together to form one light collecting area; for example, the first optical collector 101 is at working state, while the second optical collector 102 is at un-working state; or, the first optical collector 101 is at un-working state, while the second optical collector 102 is at working state. So the light transmitting path for the first optical collector 101 and the second optical collector 102 can share one light transmitting path or different transmitting paths according to the scope of the present disclosure.

The above descriptions are merely embodiments of the present disclosure, and the present disclosure is not limited thereto. A modifications, equivalent substitutions and improvements made without departing from the conception and principle of the present disclosure shall fall within the protection scope of the present disclosure.

1. An inspecting tool for inspecting a micro light emitting diode (LED) array panel, comprising:
an optical collector group configured to collect light emitted from a micro LED array included in the micro LED array panel;
an image detector connected with the optical collector group to receive the light collected by the optical collector group, and configured to capture an image of the micro LED array; and
a light measuring device electrically connected with the optical collector group to receive the light collected by the optical collector group, and configured to measure the light emitted from one or more portions of the micro LED array,
wherein the optical collector group is configured to receive the light emitted from any position of the micro LED array.

2. The inspecting tool for inspecting the micro LED array panel according to claim 1, wherein, the optical collector group comprises a first optical collector and a second optical collector; wherein, the first optical collector is connected with the image detector; the second optical collector is electrically connected with the light measuring device; the first optical collector is disposed above and vertically aligned with the micro LED array; and the first optical collector is configured to direct the light emitted from the micro LED array to the image detector.

3. The inspecting tool for inspecting the micro LED array panel according to claim 2, wherein, one or more portions of the second optical collector has a concave curved surface facing the micro LED array panel.

4. The inspecting tool for inspecting the micro LED array panel according to claim 3, wherein, the second optical collector is configured to at least comprise the concave curved surface at one or more sides of the first optical collector or around the first optical collector and above the micro LED array panel, and the micro LED array panel is arranged at a center of the concave curved surface, the concave curved surface being used for collecting the light emitted from one or more portions of the micro LED array.

5. The inspecting tool for inspecting the micro LED array panel according to claim 4, wherein, the second optical collector is not connected with the first optical collector and does not contact a sidewall of the first optical collector.

6. The inspecting tool for inspecting the micro LED array panel according to claim 3, wherein, an optical transmitting channel is configured between the first optical collector and the image detector; wherein, the second optical collector is configured at least comprising the concave curved surface at one or more sides of the optical transmitting channel or around the optical transmitting channel, and above the micro LED array panel, and the micro LED array panel is arranged at a center of the concave curved surface, the concave curved surface being used for collecting the light emitted from one or more portions of the micro LED array.

7. The inspecting tool for inspecting the micro LED array panel according to claim 6, wherein, the second optical collector is not connected with the optical transmitting channel and does not contact the sidewall of the optical transmitting channel.

8. The inspecting tool for inspecting the micro LED array panel according to claim 2, wherein, a filter is arranged between the first optical collector and the image detector.

9. The inspecting tool for inspecting the micro LED array panel according to claim 3, wherein, the second optical collector is configured at least comprising the concave curved surface at one or more sides of the micro LED array panel or around the micro LED array panel, and the micro LED array panel is arranged at a center of the concave curved surface, the concave curved surface being used for collecting the light emitted from one or more portions of the micro LED array.

10. The inspecting tool for inspecting the micro LED array panel according to claim 9, wherein, the second optical collector is an integrating semi-sphere with the micro LED array panel disposed in the center of the semi-sphere; wherein, an opening is formed at atop of the semi-sphere for inserting the first optical collector.

11. The inspecting tool for inspecting the micro LED array panel according to claim 3, wherein, the whole surface of the second optical collector is curved.

12. The inspecting tool for inspecting the micro LED array panel according to claim 3, wherein, a detecting area of the first optical collector is not less than a light emitting area of the micro LED array.

13. The inspecting tool for inspecting the micro LED array panel according to claim 12, wherein, a detecting area of the second optical collector is larger than the light emitting area of the micro LED array.

14. The inspecting tool for inspecting the micro LED array panel according to claim 12, wherein, a detecting area of the second optical collector is less than or equal to the light emitting area of the micro LED array.

15. An inspecting system for inspecting the micro LED array panel at least comprises an inspecting tool according to claim 1.

16. The inspecting system according to claim 15, wherein, the optical collector group comprises a first optical collector and a second optical collector; wherein, the first optical collector is connected with the image detector; and, the second optical collector is connected with the light measuring device; the first optical collector is disposed above and vertically aligned with the micro LED array; and the first optical collector is configured to direct the light emitted from the micro LED array to the image detector.

17. The inspecting system according to claim 16, wherein, the inspecting system further comprises a sample stage, for supporting the micro LED array panel.

18. The inspecting system according to claim 17, wherein, the second optical collector is installed on the sample stage.
